(19) United States
(12) Patent Application Publication
(10) Pub. No.: US 2007/0296315 A1
(43) Pub. Date: Dec. 27, 2007

(54) Cabinet With an Integral Framework for Air Conditioner Installation

(76) Inventor: Melquisedec Francisquini, Sao Paulo (BR)

Correspondence Address: WILLIAM J. SAPONE;COLEMAN SUDOL SAPONE P.C., 714 COLORADO AVENUE, BRIDGE PORT, CT, 06605, US

(21) Appl. No.: 11/575,614

(22) PCT Filed: Oct. 4, 2005
(86) PCT No.: PCT/BR05/00213

§ 371 Date: Mar. 20, 2007

(30) Foreign Application Priority Data
Oct. 5, 2004 (BR) PI 0404859-8

(51) Int. Cl. H05K 7/20

(52) U.S. Cl. 312/236; 361/695; 62/263

(57) ABSTRACT

IMPROVEMENTS TO THE CABINET WITH AN INTERNAL FRAMEWORK FOR MOUNTING AN AIR CONDITIONER, of the type that presents itself in the shape of a said cabinet (1), parallelepipedic and substantially elongated in its height, in such a manner that inside different folded sheet metal parts may be installed thus configuring compartments may be formed or set up to house the usual refrigeration components: compressor s (2), radiator (3) with its respective fan (4) and a condenser (5) with its respective fan (6), in such a manner that this unit may make up two air flows, one internal (7A) and the other external (7B) and for this end the cabinet (1) initially presents two rear openings, an upper one for the indraught (8) and a lower one for exhaust (9), between which the radiator (3) and its respective fan are mounted (4), thus making up the flow conditioned air (6) which on the opposite or external side is positioned in parallel in relation to the external airflow (7), this also completes the other two openings, one for indraught (10) located on the cabinet's front (1) and one on top (11), between which the unit made up of the condenser (5) and its respective fan (6).

### FIELD OF INVENITON

More in particular the current invention refers to technical and functional improvements, especially developed with the view of characterising efficient means in installing an air conditioner for different applications, especially in various electrical panels.

### CONDITION OF THE TECHNIQUE

Currently there are different types of air conditioners for the abovementioned applications, nevertheless all of them have internal compartments, which are not modular and are obtained with a considerable number of parts so that the various leak proof compartments may be made for the electrical and mechanical parts, being that the said compartments still put together individual different parts to make up the mounting supports for the condenser and its respective fan, as well as for the radiator and its respective fan in such a manner that these sets make up two systems with independent air flow, one being internal and the other being external, consequently in the usual equipment these two systems are assembled with varied mechanical components, requiring a large number of parts, which makes eventual preventive or corrective maintenance difficult, as well as characterising complex assembly and special caution as to the sealing between the two air flow systems, consequently the product's final cost is substantially increased.

### INVENTION'S OBJECTIVES

The invention's first objective is the realisation of a cabinet made totally out of sheet metal where each part is specially designed with details which compete for a simple top or side mount starting with a vertical chassis, equally designed from sheet metal, being that this chassis besides having two openings indraught and exhaust for the internal airflow (air conditioning), also includes construction details to accept other sheet metal parts, starting with a lower base, as if it were a tray, makes up the first assembly platform to stably support the compressor, over which an enclosure is placed in the form of a sheet metal box for the radiator and its respective fan, this box fits with those two openings to make up the chamber for air circulation, being that at the same time this box makes up the structural part to mount the condenser's chamber and its respective fan, thus finalising the assembly of the unit whose closing off is completed by side and top covers, each with an opening that characterises the indraught and exhaust of the outside airflow.

Therefore the objective of the invention is the combination of the different folded sheet metal parts in combination with each other to define a practically modular mechanical construction, which on the one hand makes for a simplified project both with reference to the manufacturing of the components as well as its assembly, other advantages are evident especially with reference to the structural resistance and the efficient degree of sealing at the desired points.

The combination of a superimposed fitting with the different sheet metal parts also allows for the forming of compact compartments, each for the mounting of a unit, where such compartments confer efficient spaces for mounting with the due degree of insulation for the electrical and refrigeration components with the added advantage that all these units are easily accessible, consequently such a minimised arrangement confers the necessary means in speeding up the assembly process as well as eventual preventive and corrective maintenance.

The use of different sheet metal components in making up the internal compartments as well as the structure, compete in making up a compact and substantially light air conditioner, with the inclusion of a substantial reduction in costs.

### DESCRIPTION OF THE DRAWINGS

To better understand the current invention a detailed description is made, making reference to the attached drawings where:

FIG. 1 represents a view from the top front showing the exterior details of the front cover as well as the indraught and exhaust of the outside airflow;

FIG. 2 shows another view in perspective, but, from the top rear angle, highlighting the openings which make up the indraught and exhaust of the interior airflow;

FIG. 3 illustrates from a perspective point of view with the parts being transparent, only exemplifying the air conditioner installed in an electrical cabinet, highlighting both the internal and external airflow, in which the first is really for climate control of the inside of the referred to cabinet;

FIG. 4 is a front elevation view, practically as a cut-out, only showing the different internal refrigeration components, which are the usual equipment of said nature;

FIG. 5 shows a view from the side elevation, similar to the previous one so as only to show the internal refrigeration components;

FIG. 6 reproduces the view in an exploded perspective, without the refrigeration components, highlighting the parts obtained from folded sheet metal;

FIG. 7 is a view similar to the previous one, but from a different angle, showing other details of the sheet metal components;

FIGS. 8 to 10 are the partially exploded views so as only to show the internal components of the folded sheet metal;

FIGS. 11 and 12 are the amplified details in perspective, showing the constructive details of the door locks; and

FIGS. 13 to 16 also show in perspective, highlighting the assembly box for the electrical components, especially the thermostat.

### DETAILED DESCRIPTION OF THE INVENTION

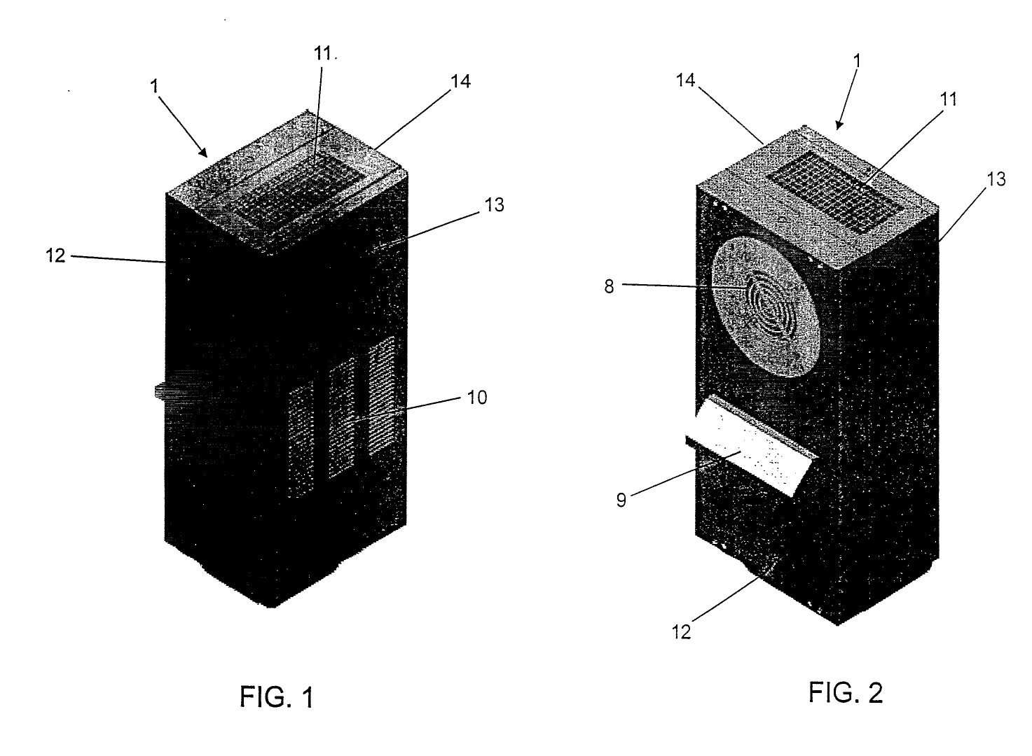

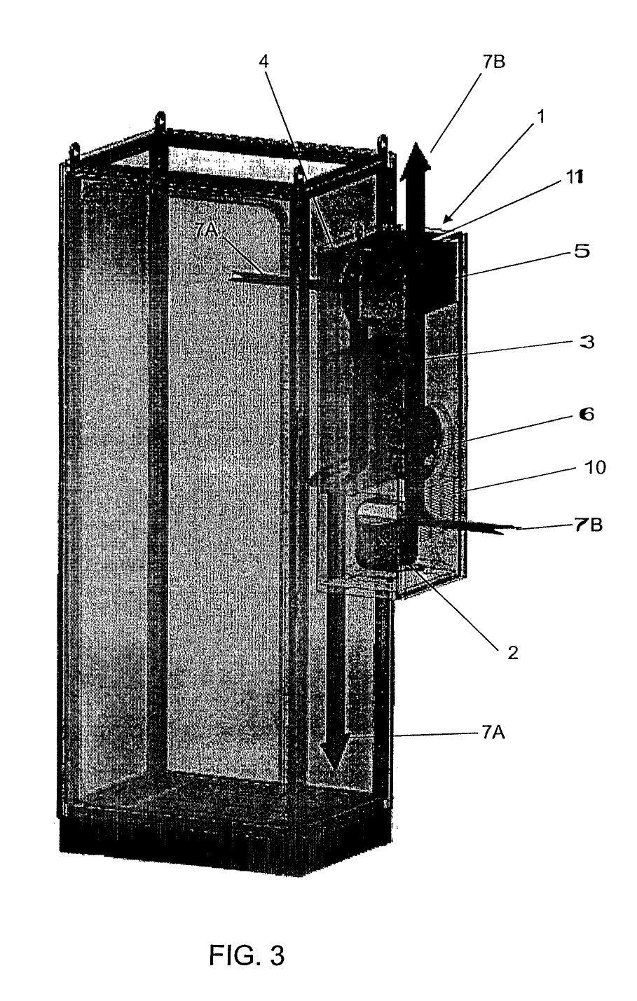

In accordance with these illustrations and its details more in particular FIGS. 1 to 3, the current invention, IMPROVEMENTS TO THE CABINET WITH AN INTERNAL FRAMEWORK FOR MOUNTING AN AIR CONDITIONER, and the manner in which the cabinet presents itself (1), parallelepipedic and substantially elongated in its height, in such a manner that in its inside (FIG. 3) different compartments may be formed or assembled to house the usual refrigeration units: compressor (2), radiator (3) with its respective fan (4) and a condenser (5) with its respective fan (6), in such a manner that this unit may make up two air flows, one internal (7A) and the other external (7B) and for this end the cabinet (1) initially presents two rear openings, an upper one for the indraught (8) and a lower one for exhaust (9), between which the radiator (3) and its respective fan are mounted (4), thus making up the flow of conditioned air (6) which on the opposite or external side is positioned in parallel in relation to the external airflow (7), this also completes the other two openings, one for indraught (10) located on the cabinet's front (1) and one on top (11), between which the unit made up of the condenser (5) and its respective fan (6).

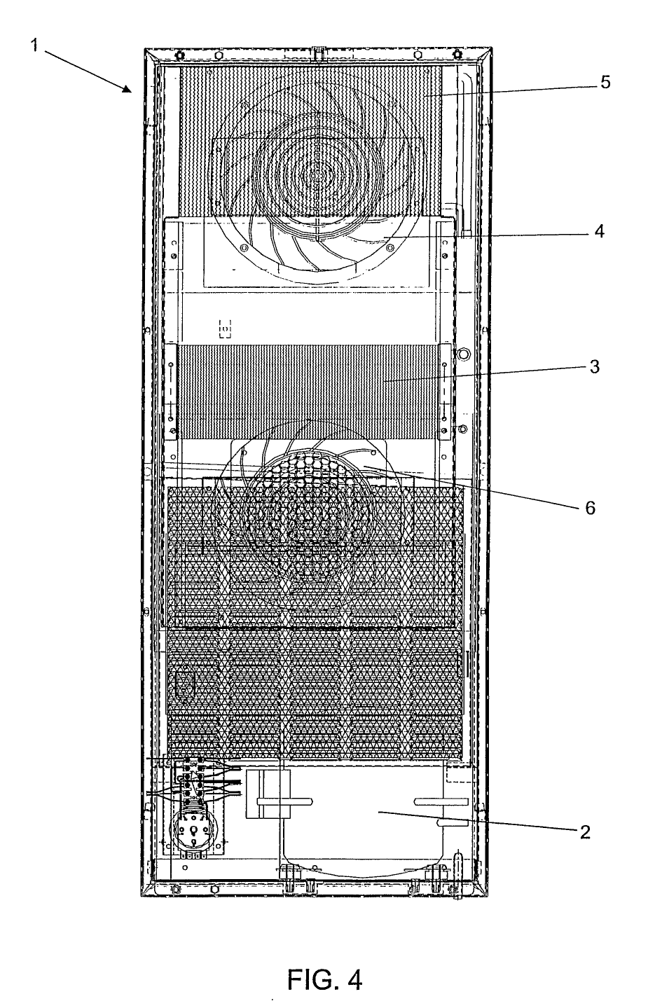

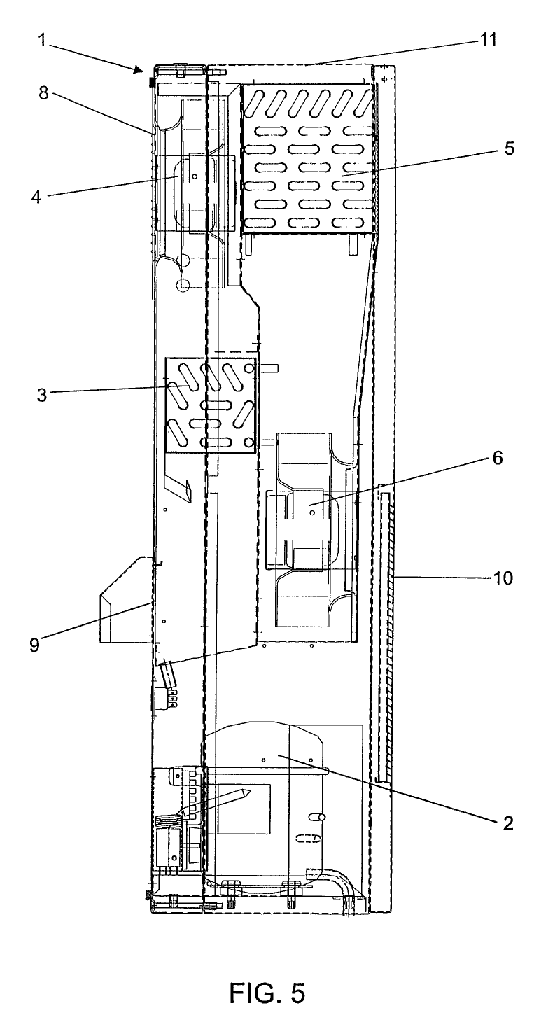

FIGS. 4 and 5 show in greater detail the internal refrigeration components and its respective electrical parts, where it can be seen that the said components are common in different air conditioners.

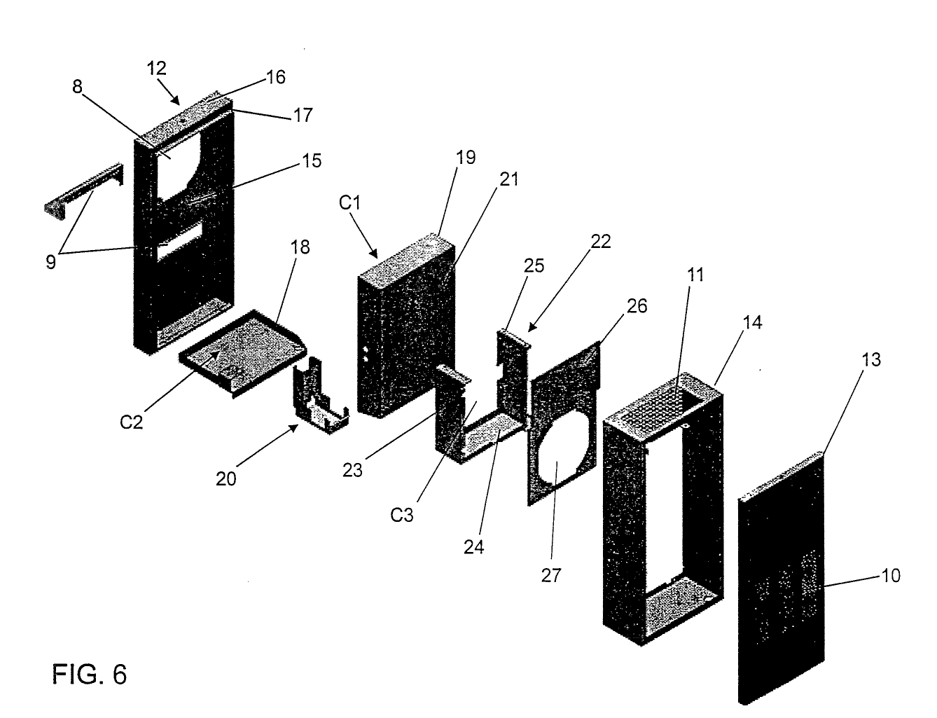

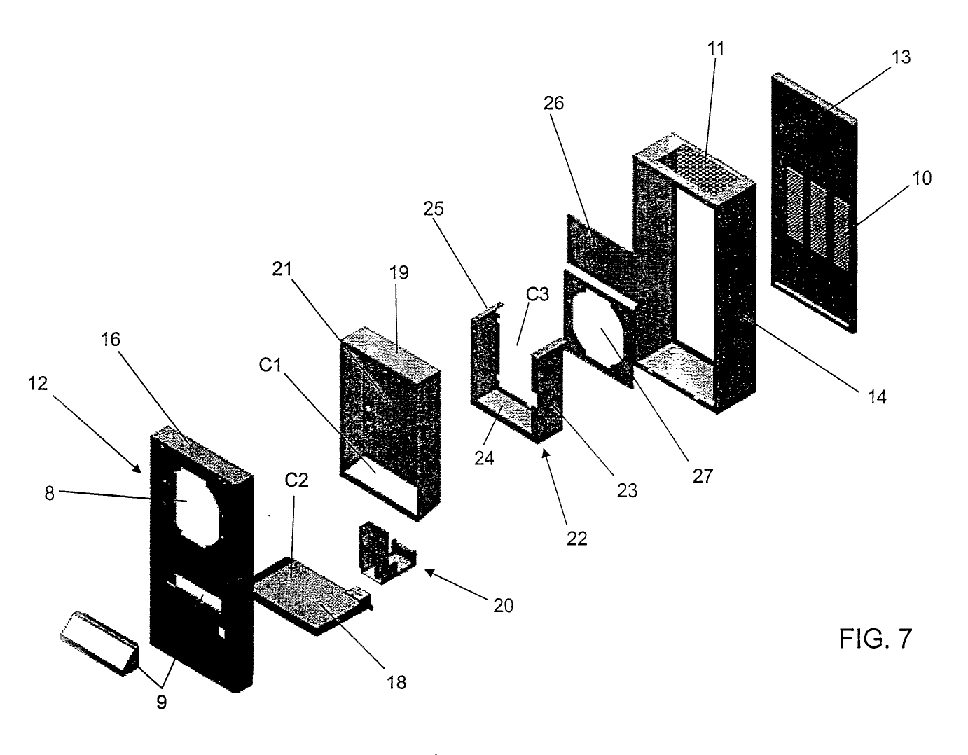

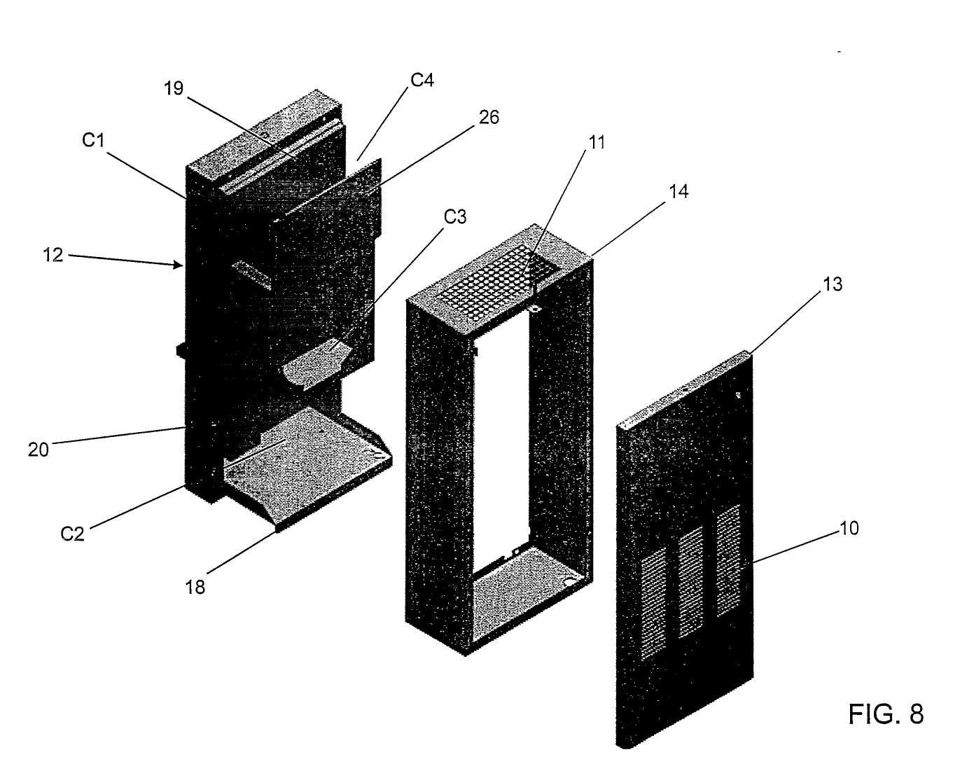

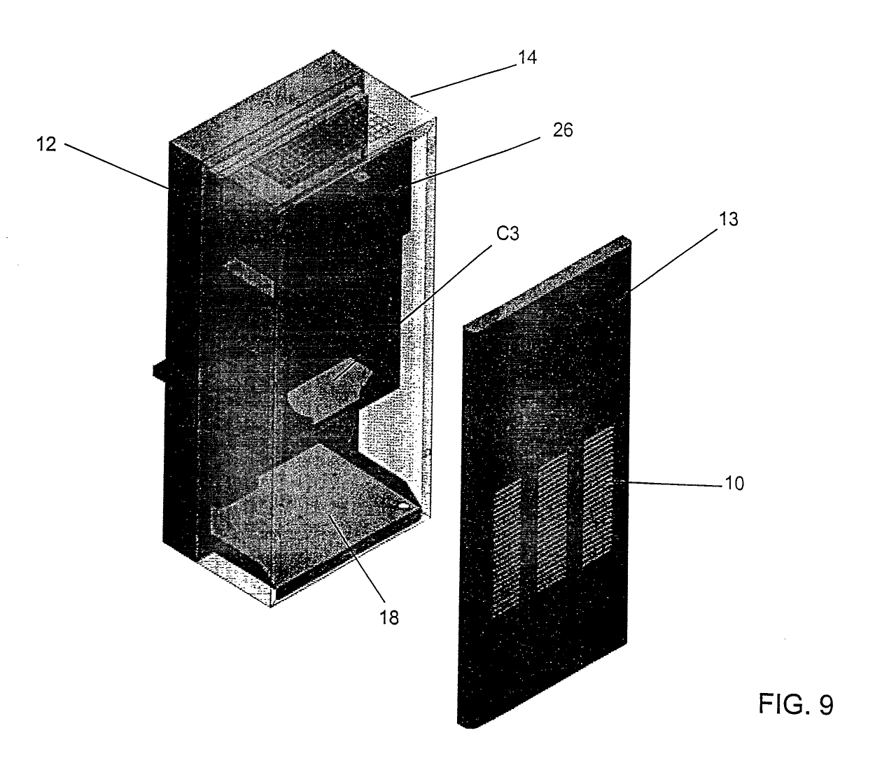

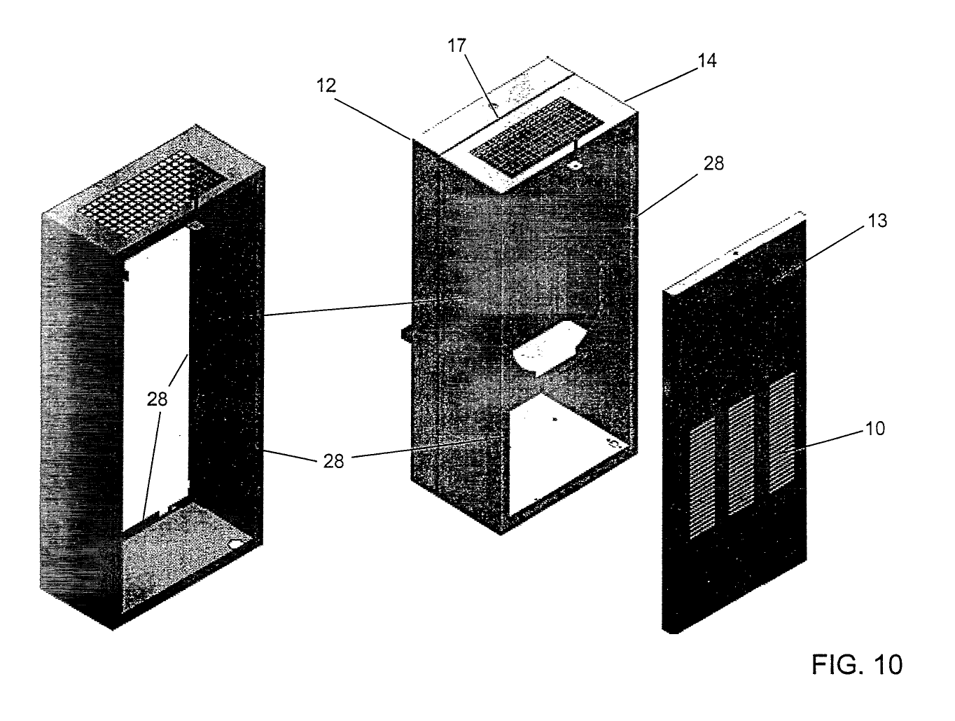

In relation to FIGS. 6, 7, 8 and 9, the current IMPROVEMENTS TO THE CABINET WITH AN INTERNAL FRAMEWORK FOR MOUNTING AN AIR CONDITIONER, is characterised by the fact that it encompasses a set of folded sheet metal parts and set in such a manner that it is fitted onto the vertical chassis (12), rear, and a front cover (13), with these two parts being spaced one from the other by an enclosure in a box format (14), as well as the said vertical chassis (12), it has a back or rear wall (15) with the two openings that configure the indraught (8) and exhaust (9) of the internal airflow (7A), the first mentioned has a grill, whilst the latter has a downward facing opening, as well as the said vertical chassis (12) has its depth defined by side walls (16), whose front edges are folded inwards as well as outwards (17), forming the fitting for closing (14), forming a spacious compartment in whose interior are other equally folded sheet metal parts, starting with a square base (18), practically in the shape of a tray, fitted to the lower wall of the vertical chassis (1), in such a manner that on top of this another part in the form of a box may be placed (19) which in its turn before assembling the parts (14-13), is fastened to the inside of the vertical chassis (12), where the open rear side of the said box (19) and is fitted against the back (15), where the openings are circumscribed (8-9) forming a compartment (C1) to mount the radiator (3) and its respective fan (4) and at the same time, with the assembly of the said box (19), making up two other mounting possibilities, in which the first is another compartment (C2) (FIG. 8) to mount the compressor (2) and the usual electrical parts built-in into a box (20), whilst the second one is made up by the back wall itself (21) of the box (19), against which is affixed another sheet metal housing in a “U” shape (22), defined by two vertical side walls (23) and a back wall (24), all of them with mounting tabs (25) facing inwards, in such a manner that the said housing (22) may on the one side be affixed to the back (21) of the box (19) and on the opposite side it will have the closing off plate (26) with a spacious opening (27), which will make up two compartments (C3-C4), one of them in front of the housing (22) itself, affording a housing for the fan to be mounted (6), and an upper compartment for the condenser to be mounted (5) which in its turn is positioned over the air exhaust (11) made up by that enclosure (14), while the other indraught opening (10) on the lid (13) remains aligned to the opening (27) of the closing off plate (26), thus making up that external airflow (7B).

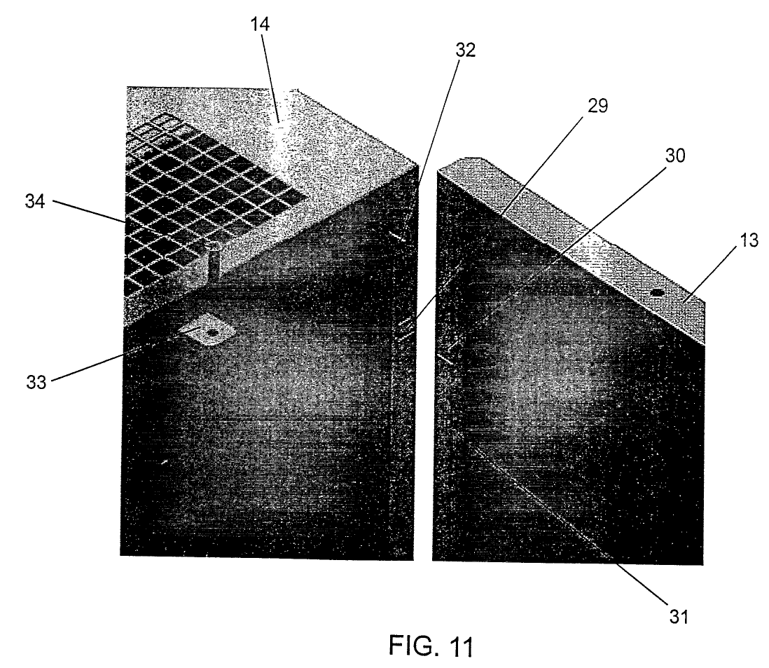

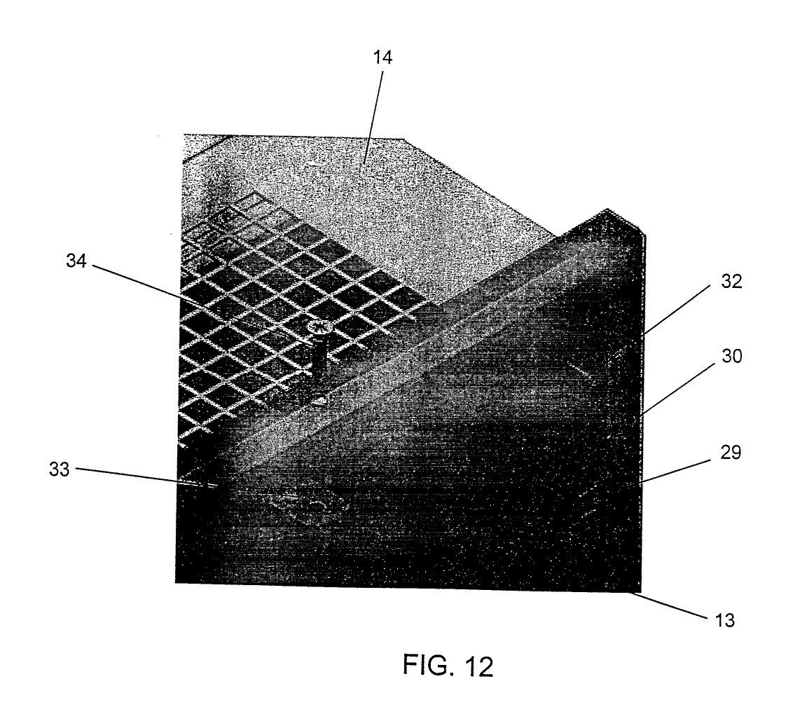

As shown in figure (10), the box shaped enclosure (14) has all its front and rear edges perpendicularly folded inwards thus making up the mounting tabs (28), where the rear ones afford adjustment for the fittings (17) of the vertical chassis (12), while the front and vertical ones have, just as is shown in FIGS. 11 and 12, pressed or cut out pieces in such a manner as to make locking tabs (29), two or more on each side, all of them folded upwards in an awaiting hook position so as to fit in the openings (30) existing on the other inwardly facing perpendicular tabs (31) existing on the cover (13), whose closeness against the enclosure (14) is guided by other tabs (32) perpendicularly set outward facing and existing on the referred to tabs (28) of the enclosure (14) which, finally includes one final upper tab (33) perpendicularly set outward facing to remain on the upper edge of the cover (13), where the final affixing is completed with a screw (34). In the manner as shown in FIG. 12, the placing of the said cover (13) is carried out in a fast, simple manner, that is, it is set against the enclosure in the shape of a box (14) in a position slightly upwards offset, logically guided by the tabs (32) and, after the said cover is put on it is displaced downwards, the moment in which the locking tabs penetrate (29) the openings (30), consequently the said cover is locked, aligned in position with the enclosure (14) and by means of the screw (34) its fastening is completed.

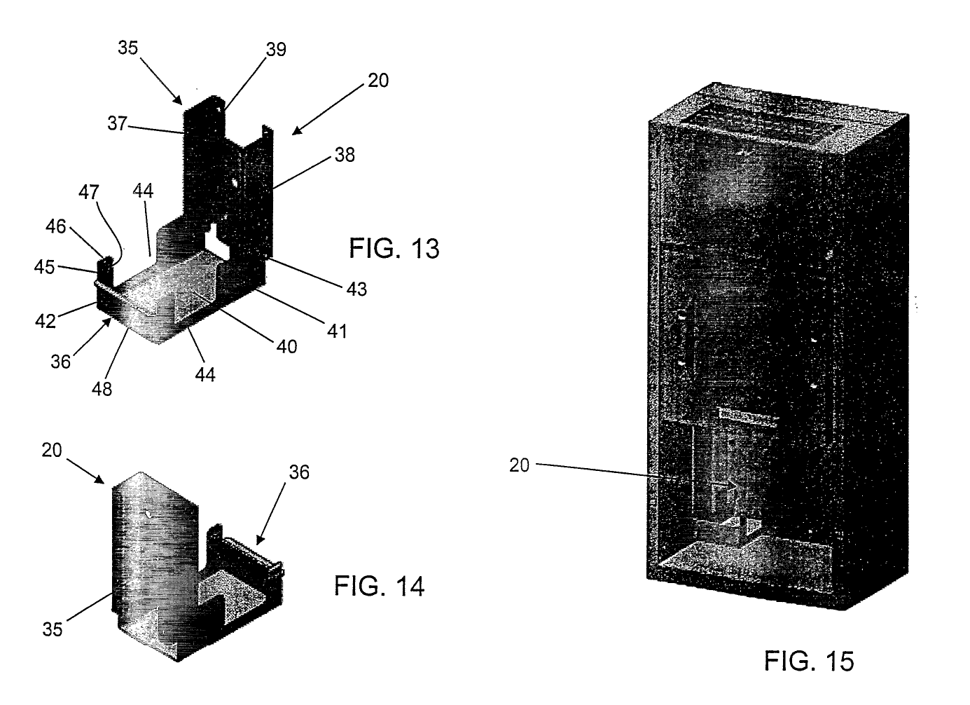

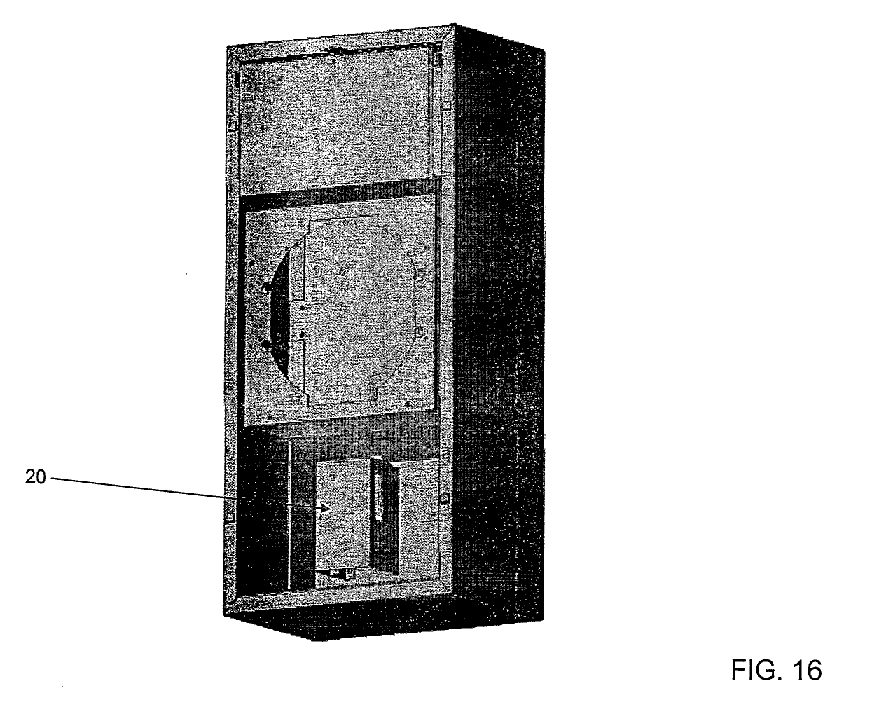

In relation to FIGS. 13, 14 and 15, the electrical components assembly box (20) is made up of two folded sheet metal parts, one fixed (35) and the other tilting (36), this last mentioned one is in the shape of a cover, whilst the first constitutes a true support for the electrical components, mainly the thermostat and its respective button, and as such the said affixed part presents its transversal “C” section folding forwards, that is, it presents one front wall (37) with the appropriate holes and cut outs, as well as its side edges which fold backward forming the three side walls (38) which, in the same manner, folding inwards in the shape of fastening tabs (39), whilst the other movable piece, named the cover (36), has a similar shape, that is, it includes a front wall (40), whose side and upper edges fold inwards (41-42), upon which the lower extremities of the side walls (41) fit on top of the sides (38) for its articulated fastening (43) and still these same side walls (41) have cut outs (44) forming two claw like flexible tabs (45) with open ends (46) and details (47) which afford the means so that the said cover remains closed (FIG. 16) only with slight pressure and by means of a simple tilting movement, and having as its closing limit the tab (48) formed by the wall (42) and with this, the body (35) and the cover (36) practically make up two housings, in which the cover allows for easy access to the thermostat button.

As it can be seen after what has been said and shown, the improvement in question sets all those previously described advantages, as all the sheet metal used was designed to idealise a compact, light and operational air conditioner, adding efficiency at a lower cost, not only with reference to the installation and assembly of the unit, but also with eventual preventive and corrective maintenance, as, in this case, access is very easy and fast with access to the internal components of the device, which considerably diminishes the stoppage time.

1-3. (canceled)

4. A cabinet having an internal framework for mounting an air conditioner, said cabinet comprising:
a vertical chassis (12) having a back wall (15) with a pair of openings for inflow and outflow of an internal air stream (7A), the vertical chassis having a lower wall, an upper wall and a pair of side walls for forming a compartment therein;
a base (18) forming a tray fitted to the lower wall of the vertical chassis;
a box (19) mounted to the wall (15) of the vertical chassis, the box forming a compartment (C1) for housing of a radiator and a fan therein, the compartment (C1) containing the internal air stream (7A) passing through the pair of openings in the vertical chassis;
a U-shaped housing (22) defined by two vertical side walls and a bottom wall (24), the U-shaped housing being affixed to a back (21) of the box;
a closing off plate (26) fixed to a front of the U-shaped housing, for forming a fan compartment for a condenser fan mountable therein, having an opening for external air to flow therethrough;
an enclosure (14) having side walls, a bottom wall and a top wall, the enclosure having an air exhaust opening for completing an exhaust air path (7B) therethrough, the enclosure (14) attached to the vertical chassis, to enclose the base, the box, the U-shaped housing and the closing off plate assembled with the vertical chassis therein; and,
a cover (13) mounted to the enclosure (14), the cover having air intake openings therein to allow external air to flow therethrough.

5. The cabinet of claim 4 wherein the base defines a compartment for housing of a compressor therein.

6. The cabinet of claim 4 wherein the base defines a compartment for housing of an electrical component box (20) therein.

7. The cabinet of claim 4 wherein the closing off plate defines an upper condenser compartment, the enclosure having the exhaust openings in the top wall thereof adjacent to the upper condenser compartment.

8. The cabinet of claim 4 wherein the U-shaped housing has mounting tabs (25) facing inwards for fixing said housing (22) to a back (21) of the box (19) and to the closing off plate (26).

9. The cabinet of claim 4 wherein the enclosure (14) has front and rear edges perpendicularly folded inwards for forming mounting tabs (28), the rear mounting tabs being adjustable for mating to fittings (17) provided on the vertical chassis (12), front and vertical mounting tabs forming locking tabs (29), two or more located on each side and folded upwards in an awaiting hook position so as to fit in openings (30) provided on inwardly facing perpendicular tabs (31) provided on the cover (13), the cover being guided close against the enclosure (14) by tabs (32) perpendicularly set outward facing the mounting tabs (28), one final upper tab (33) perpendicularly set outward facing to remain on an upper edge of the cover (13), for final affixing by receiving a screw (34).

10. The cabinet of claim 4 further comprising an electrical components box (20) made of two parts, one fixed (35) and the other tilting (36) to form a cover, the first part being a support for electrical components.

11. The cabinet of claim 10 wherein the electrical components box cover has side and upper edges folded inwards (41-42), upon which lower extremities of the side walls (41) fit on top of sides (38) for articulated fastening (43).

12. The cabinet of claim 11 wherein the same side walls (41) have cut outs (44) forming two claw like flexible tabs (45) with open ends (46) and details (47), whereby said cover remains closed only with slight pressure and a simple tilting movement.
